(19) United States
(12) Patent Application Publication
(10) Pub. No.: US 2009/0068449 A1
(43) Pub. Date: Mar. 12, 2009

(54) METHOD FOR MANUFACTURING TITANIUM DIOXIDE THIN FILM

(75) Inventors: Jui-Kai HU, KAOHSIUNG CITY (TW); Hung-Chang CHEN, TU-CHEN CITY (TW); Wen-Ting LIN, CAOTUN TOWNSHIP (TW)

Correspondence Address: SUGHRUE MION, PLLC, 2100 PENNSYLVANIA AVENUE, N.W., SUITE 800, WASHINGTON, DC, 20037, US

(73) Assignee: TAIWAN TEXTILE RESEARCH INSTITUTE, TU-CHEN CITY (TW)

(21) Appl. No.: 11/967,763

(22) Filed: Dec. 31, 2007

(30) Foreign Application Priority Data
Sep. 12, 2007 (TW) 96134109

(51) Int. Cl. B32B 9/04; C23C 14/34

(52) U.S. Cl. 428/336; 204/192.14; 428/702

(57) ABSTRACT

A vacuum chamber having a TiO₂ target and a base therein is first provided wherein a plastic substrate is fixed onto the base. After that, a plasma gas consisting of argon and oxygen is filled into the vacuum chamber. The filling pressure of the plasma gas is in the range of 1˜10 Pa and the flow ratio of argon to oxygen thereof is in the range of 9:1˜7:1. Finally, an anatase TiO₂ layer is formed on the plastic substrate by sputtering, wherein the temperature of the plastic substrate is kept between 50˜180 during the sputtering.

### RELATED APPLICATIONS

This application claims priority to Taiwan Application Serial Number 96134109, filed Sep. 12, 2007, which is herein incorporated by reference.

### BACKGROUND

1. Field of Invention

The present invention relates to a method for manufacturing thin films. More particularly, the present invention relates to a method for manufacturing TiO₂ thin films.

2. Description of Related Art

TiO₂ featured by its anti-fog, anti-contamination, and odor removal properties has been widely applied in our everyday lives. TiO₂ is usually sprayed or coated on the surfaces of fabrics and commodities to allow these objects to exhibit such featuring properties provided by TiO₂. However, only anatase TiO₂ is able to provide such features.

The above mentioned spraying or coating processes have the problem of poor adhesion between the TiO₂ thin film and the plastic objects. Therefore, sol-gel method for forming a TiO₂ thin film on a plastic substrate has been proposed to avoid such problem, but usually the TiO₂ thin film formed whereby is not an anatase TiO₂ or alternatively the anatase TiO₂ could be formed by a high-temperature sintering process but the plastic substrate is destroyed under such high temperature.

In view of the forgoing, it is proposed to use a sputtering process to form a TiO₂ thin film. In the known TiO₂ sputtering process the temperature of the conductive substrate being processed is usually higher than 200 so that an anatase TiO₂ could be formed. In addition, as a result of the bombardment of plasma ions, the temperature of the substrate will increase. In this case, the substrate to be sputtered needs to be thermally resistance at temperature higher than 200° C., meaning the selection of substrate is critical and limited. Accordingly, how to obtain an anatase TiO₂ thin film at low temperature is of great importance and has received significant attention recently.

### SUMMARY

A method for manufacturing TiO₂ thin films is provided in the present invention.

According to one embodiment of the present invention, a method for manufacturing TiO₂ thin film is provided. First, a vacuum chamber containing a TiO₂ target and a base inside the chamber is provided wherein a plastic substrate is placed on the base. After that, a plasma gas consisting of argon and oxygen is filled into the vacuum chamber. The filling pressure of the plasma gas is 1˜10 Pa and the flow ratio of argon to oxygen thereof is in the range of 9:1˜7:1. Finally, an anatase TiO₂ layer is formed on the plastic substrate by sputtering, wherein the temperature of the plastic substrate is kept between 50˜180 during the sputtering.

According to another embodiment of the present invention, a structure with TiO₂ layer is provided, wherein the structure comprises a plastic base and an anatase TiO₂ layer. The TiO₂ layer is formed on the surface of the plastic base by a sputtering process and the transparency of the TiO₂ layer at visible light wavelength of 380˜780 nm is about 65˜90%. The temperature of the vacuum chamber is kept between 70˜100° C. The vacuum chamber contains a TiO₂ target and a plasma gas consisting of argon and oxygen wherein the filling pressure of the plasma gas is 1˜10 Pa and the flow ratio of argon to oxygen thereof is in the range of 9:1˜7:1.

According to the embodiment of the present invention, the method for manufacturing TiO₂ thin film provided allows an anatase TiO₂ thin film to be formed at a lower temperature. In addition, the anatase TiO₂ thin film formed has good transparency and exhibits good hydrophilic property through short-term irradiation.

### BRIEF DESCRIPTION OF THE DRAWINGS

The invention can be more fully understood by reading the following detailed description of the embodiment, with reference made to the accompanying drawings as follows:

FIG. 1 is a flow chart illustrating the process of manufacturing a TiO₂ thin film according to one embodiment of the present invention;

FIG. 2 is a schematic diagram illustrating the sputtering apparatus used in the manufacturing process described in FIG. 1;

FIG. 3A is X-ray diffraction patterns of a PC substrate coated with a TiO₂ thin film according to one embodiment of the present invention;

FIG. 3B is X-ray diffraction patterns of a PEN substrate coated with a TiO₂ thin film according to one embodiment of the present invention;

FIG. 4 is transparency measurements of a PC substrate coated with a TiO₂ thin film according to one embodiment of the present invention;

FIG. 5A is hydrophilic analysis for a UV irradiated PC substrate coated with a TiO₂ thin film according to one embodiment of the present invention; and

FIG. 5B is hydrophilic analysis for a UV irradiated PC substrate coated with a TiO₂ thin film of various thicknesses according to one embodiment of the present invention.

### DETAILED DESCRIPTION

Reference will now be made in detail to the present embodiments of the invention, examples of which are illustrated in the accompanying drawings.

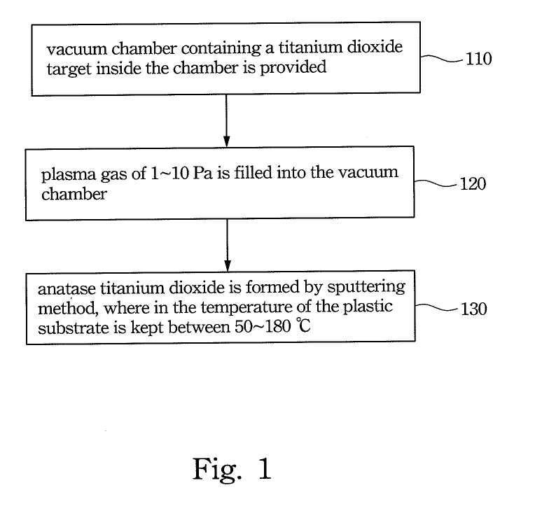

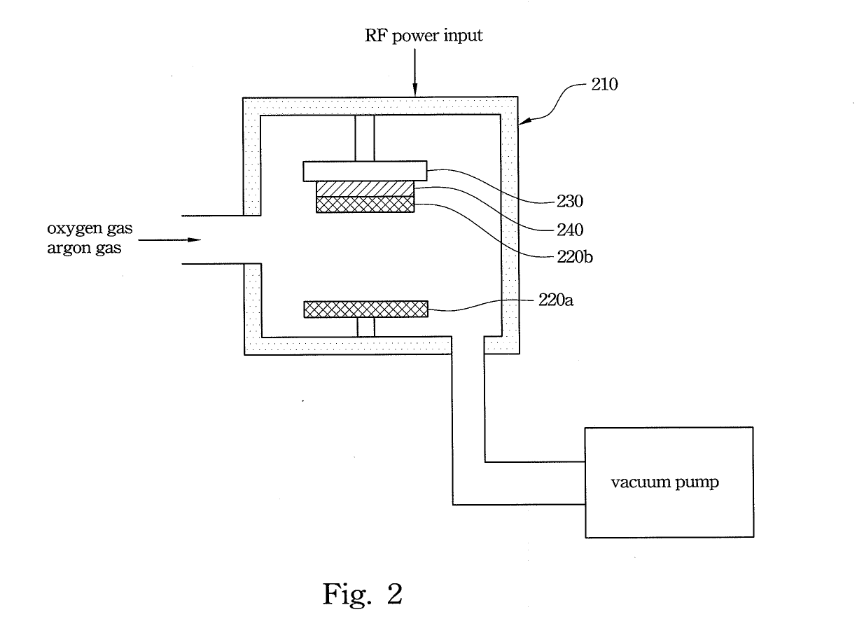

FIG. 1 is a flow chart illustrating the process of manufacturing a TiO₂ thin film according to one embodiment of the present invention, FIG. 2 is a schematic diagram illustrating the sputtering apparatus used in the manufacturing process described in FIG. 1. Refer to FIG. 1 and FIG. 2. First, at step 100, a vacuum chamber 210 having a TiO₂ target 220a and a base 230 therein is provided. A plastic substrate 240 is placed onto the base 230. The distance between the TiO₂ target 220a and the plastic substrate 240 is about 80˜100 mm. The plastic substrate 240 is a transparent substrate such as polyethylene naphthalene (PEN), polycarbonate (PC), or polyethylene terephthalate (PET).

Then, at step 120, a plasma gas consisting of argon and oxygen is filled into the vacuum chamber 210, wherein the filling pressure of the plasma gas is 1˜10 Pa and the flow ratio of argon to oxygen therein is 9:1˜7:1.

Finally, at step 130, an anatase TiO₂ layer 220b is formed on the plastic substrate 240 through sputtering wherein the thickness of the TiO₂ layer is about 0.1˜1.5 μm and temperature of the plastic substrate is kept between 50˜180 during the sputtering. The sputtering method can be RF (radio frequency) magnetron sputtering.

### EXAMPLE

According to the above mentioned embodiment, RF magnetron sputtering method is used to demonstrate the TiO₂ thin film manufacturing process with a plasma gas of 1 Pa, 2 Pa and 3 Pa. The plastic substrate used is PC or PEN, the distance between the TiO₂ target 220a and the plastic substrate 240 is about 80 mm, and the flow ratio of argon to oxygen in the plasma gas is about 8:1.

After the TiO₂ thin film has been formed, several properties such as crystal phase, transparency, hydrophile, and adhesivity between the substrate and the TiO₂ thin film are subsequently analyzed. The results are shown as following:

### Crystal Phase and Transparency Analysis

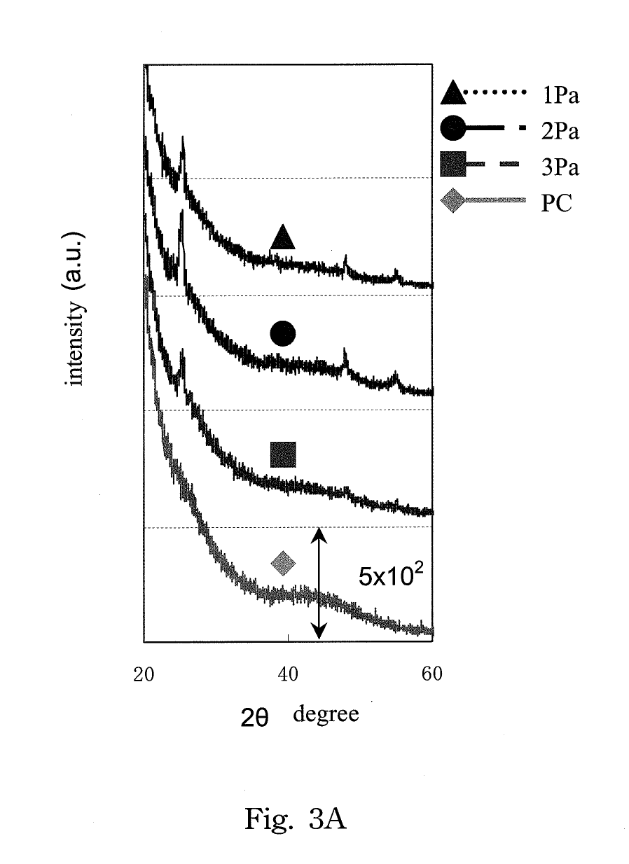

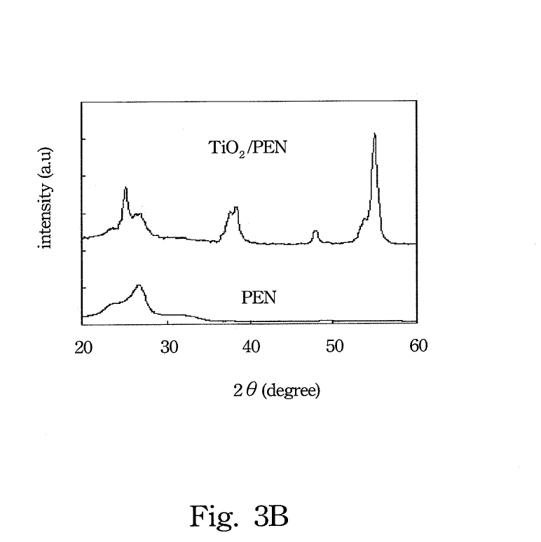

FIG. 3A is X-ray diffraction patterns of a PC substrate coated with a TiO₂ thin film according to one embodiment of the present invention; FIG. 3B is X-ray diffraction patterns of a PEN substrate coated with a TiO₂ thin film according to one embodiment of the present invention. The results shown in FIG. 3A and FIG. 3B prove the TiO₂ thin film formed by low temperature sputtering method contains anatase phase. The anatase TiO₂ thin film is able to initiate photocatalysis under UV irradiation such that some of the odor molecules can be degraded and no longer has the characteristics that made it an odor.

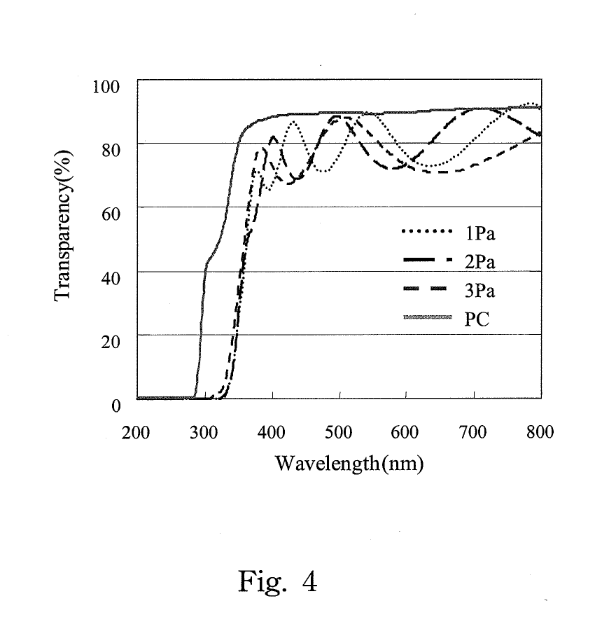

FIG. 4 is transparency measurements of a PC substrate coated with a TiO₂ thin film according to one embodiment of the present invention, FIG. 4 shows the transparency of the PC substrate coated with a TiO₂ thin film is about 65˜90%.

### Hydrophilic Analysis

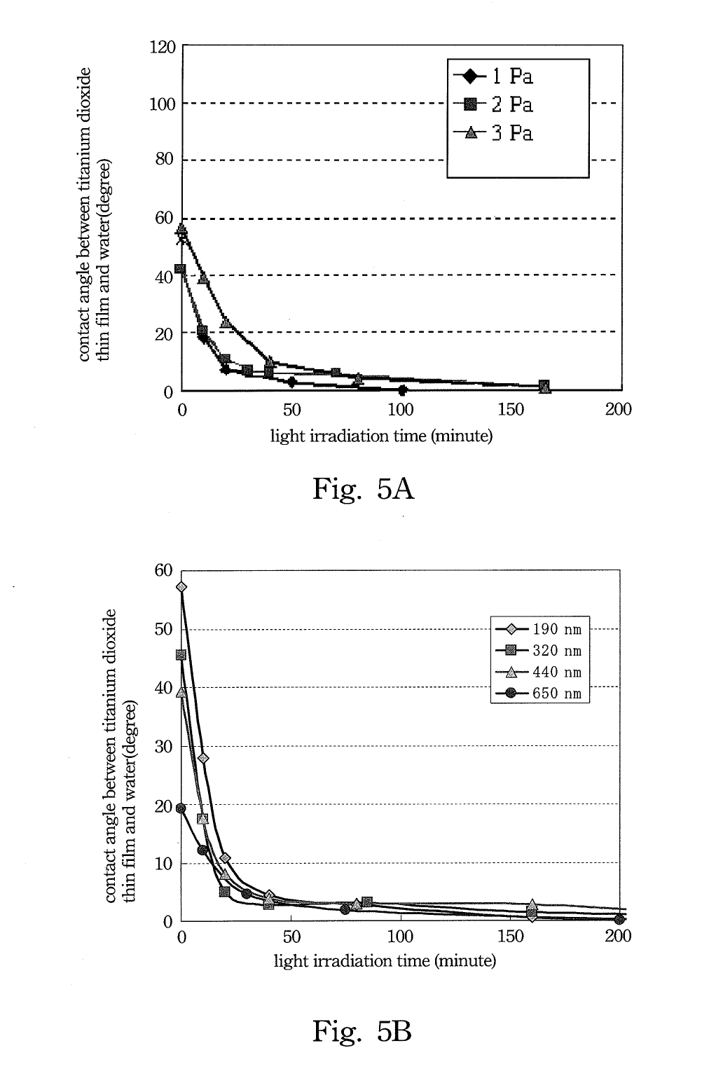

FIG. 5A is hydrophilic analysis for a UV irradiated PC substrate coated with a TiO₂ thin film according to one embodiment of the present invention; FIG. 5B is hydrophilic analysis for a UV irradiated PC substrate coated with a TiO₂ thin film of various thicknesses according to one embodiment of the present invention. FIG. 5B shows hydrophilic analysis results of a PC substrate coated with a TiO₂ under the plasma gas of 1 Pa.

Refer to FIGS. 5A and 5B, it could be noted that after 40 minutes of irradiation, the contact angle between the TiO₂ thin film and water is lower than 10 degree, which shows high hydrophilic property. Accordingly, the TiO₂ thin film formed in this embodiment only requires a very short-term irradiation such that the high hydrophilic property could be achieved. Generally, hydrophilic material can be formed on the surface of, for example, a mirror to provide an anti-fog feature.

### Analysis of Adhesivity Between the Substrate and the TiO₂ Thin Film

After the TiO₂ thin film has been formed on the PC substrate, the adhesivity between the substrate and the TiO₂ thin film is also analyzed and results are shown in Table 1. The analysis is obtained by grid method and the adhesivity is scaled by 6 levels (0 B˜5 B). About 65% area of TiO₂ thin film is completely peeled off the PC substrate and is therefore scaled as 0 B (the smallest adhesivity). The strongest adhesivity is scaled as 5 B; meaning thin film is not peeled off the PC substrate at all. The four scales between the two extremes are 1 B˜4 B which represent the area percentages of TiO₂ thin firm peeled off the PC substrate are 35˜65%, 15˜35%, 5˜15%, and <5%, respectively.

In addition, as a result of the bombardment of plasma ions the substrate temperature will increase. Therefore, a cooling system is usually required to regulate the substrate temperature. The substrate temperatures shown in Table 1 are regulated by a cooling system.

TABLE 1
analysis of adhesivity between the substrate and the TiO₂ thin film.

| | | PC substrate | |
|---|---|---|---|
| | Plasma gas pressure (Pa) | temperature (° C.) | adhesivity |
| Sample 1 | 1 | 80 | 3B |
| Sample 2 | 1 | 120 | 4B |
| Sample 3 | 2 | 50 | 3B |
| Sample 4 | 2 | 80 | 3B |
| Sample 5 | 3 | 80 | 4B |
| Sample 6 | 3 | 120 | 1B |

From the above-mentioned examples and the adhesivity test result of Table 1, it could be seen that by controlling suitable process conditions such as the filling pressure and the composition of the plasma gas, and the temperature of the substrate, a good adhesivity between the TiO₂ thin film and the PC substrate could be achieved.

In view of the foregoing, it could be appreciated that an anatase TiO₂ thin film can be formed at low temperature by the method for manufacturing TiO₂ thin film according to the embodiments of the present invention. In addition, the TiO₂ thin film formed exhibits good transparency and can be irradiated to obtain good hydrophilic property. Superior adhesivity between the substrate and the TiO₂ thin film can also be obtained if the temperature of the sputtering process can be carefully controlled.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for manufacturing a TiO₂ thin film, comprising:
providing a vacuum chamber having TiO₂ target and a base therein, wherein a plastic substrate is placed onto the base;
filling a plasma gas consisting of argon and oxygen into the vacuum chamber, wherein a filling pressure is in the range of 1˜10 Pa, and a flow ratio of argon to oxygen is in the range of 9:1 to 7:1; and
forming an anatase TiO₂ layer on the plastic substrate by a sputtering process, wherein the temperature of the plastic substrate is kept between 50˜180° C.

2. The method of claim 1, wherein the distance between the TiO₂ target and the plastic substrate is about 80˜100 mm.

3. The method of claim 1, wherein the plastic substrate is a transparent substrate.

4. The method of claim 3, wherein the transparent substrate is selected from the group consisting of polyethylene naphthalate, poly carbonate, and polyethylene terephthalate.

5. The method of claim 1, wherein the filling pressure of the plasma gas is 1˜3 Pa.

6. The method of claim 1, wherein the flow ratio of argon to oxygen is about 8:1.

7. The method of claim 1, wherein the sputtering process is a radio frequency magnetron sputtering.

8. A structure with a TiO₂ layer, comprising:
a plastic substrate; and
an anatase TiO₂ layer on the surface of the plastic substrate, wherein the transparency of the TiO₂ layer at visible light wavelength of 380˜780 nm is about 65˜90% and the TiO₂ layer is formed in a vacuum chamber by a sputtering process, wherein
the temperature of the plastic substrate is kept between 50˜180° C.; and
the vacuum chamber contains a TiO₂ target and a plasma gas consisting of argon and oxygen wherein a filling pressure thereof is in the range of 1˜10 Pa, and a flow ratio of argon to oxygen is in the range of 9:1 to 7:1.

9. The structure of claim 8, wherein the thickness of TiO₂ layer is about 0.1˜1.5 μm.
